(19) United States
(12) Patent Application Publication
(10) Pub. No.: US 2012/0103380 A1
(43) Pub. Date: May 3, 2012

(54) THERMOELECTRIC MODULE AND PROCESS FOR THE PRODUCTION THEREOF

(75) Inventors: Madalina Andreea STEFAN, Trostberg (DE); Frank Haass, Erzhausen (DE)

(73) Assignee: BASF SE, Ludwigshafen (DE)

(21) Appl. No.: 13/283,009

(22) Filed: Oct. 27, 2011

Related U.S. Application Data
(60) Provisional application No. 61/407,032, filed on Oct. 27, 2010.

(51) Int. Cl. H01L 35/32; H01L 35/34

(52) U.S. Cl. 136/224; 136/201

(57) ABSTRACT

In a process for the production of a thermoelectric module, thermoelectric legs which are electrically contact-connected in series are coated so as to be covered with an electrically insulating solid material.

The invention relates to a thermoelectric module, to a process for the production thereof and also to a thermoelectric module obtainable by the process.

A thermoelectric module (TEM) according to the prior art is made up of p- and n-legs, which are connected electrically in series and thermally in parallel.

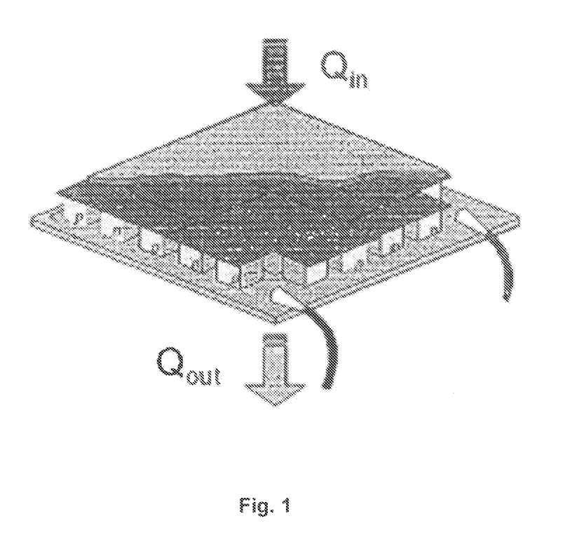

FIG. 1 shows such a module, where Qᵢₙ represents the heat input and Qₒᵤₜ represents the heat output.

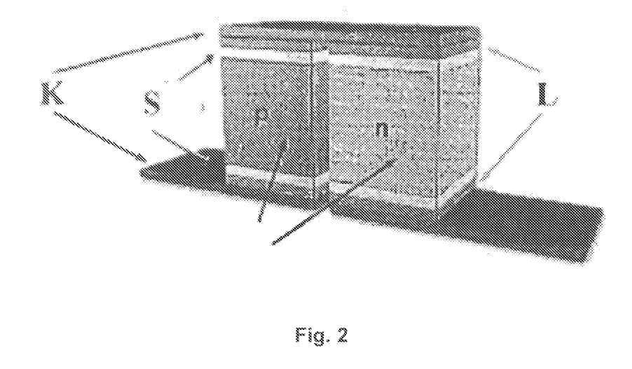

The conventional construction consists of two ceramic plates, between which the individual legs are applied in alternation. Electrical contact is made with every two legs via the end faces, as shown in FIG. 2. p- and n-legs are connected via the sequence of barrier layers (S), solder (L) and electrical contact (K).

In addition to the (electrically conductive) contact-connection, various further layers are normally also applied to the actual material, which serve as barrier layers or as solder layers. Ultimately, the electrical contact between two legs is established, however, via a metal bridge (composed of Fe, Ni, Al, Pt, Cu, Zu, Ag, Au, alloys such as steels or brass or the like).

In order to impart stability to the whole structure and to ensure the necessary, substantially homogeneous thermal coupling over the total number of legs, carrier plates are required. For this purpose, a rigid ceramic is usually used, for example composed of oxides or nitrides such as Al₂O₃, SiO₂ or AlN. These materials contribute not only to the stability but also to the electronic insulation, and have to have the appropriate thermal stability. Furthermore, the ceramic plates serve for electrical insulation. This overall structure forms a thermoelectric module (TEM).

A plurality of TEMs, which are fitted between a heat source and a heat sink and are connected electrically, usually form a thermoelectric generator.

In order to be used as a generator in the high-temperature sector above 350° C., most thermoelectric materials have to be insulated and protected by a seal from material losses resulting from sublimation or evaporation, and also against destruction or damage resulting from oxidation or other contamination with respect to an external medium, such as air. For this reason, the TEM is usually encapsulated tightly in a metal housing, as described for example in JP 2200632723.

This typical construction entails a series of disadvantages. The ceramic and the contacts can be mechanically loaded only to a limited extent. Mechanical and/or thermal stresses can easily lead to cracks or detachment of the contact-connection, rendering the entire module unusable.

Furthermore, limits are also imposed on the traditional construction, with the layer sequence of insulating plates/electrical conductor (electrode)/TE material/electrode/insulating plates, with regard to application, since only planar surfaces on the heat exchanger can ever be connected to the thermoelectric module.

A close bond between the module surface and the heat source/heat sink is advantageous for ensuring that there is a sufficient and optimum heat flow. An integral bond between all the components of the module is important for this.

It is an object of the present invention to provide a thermoelectric module and a process for the production thereof, where the disadvantages of the known thermoelectric modules should be avoided and the modules make improved heat flow possible as a result of optimized thermal coupling and also make simple and flexible encapsulation of the thermoelectric module possible.

According to the invention, the object is achieved by a process for the production of a thermoelectric module, in which process thermoelectric legs which are electrically contact-connected in series are coated so as to be covered with an electrically insulating solid material.

The object is additionally achieved by a thermoelectric module, obtainable by the above process.

The object is additionally achieved by a thermoelectric module, wherein thermoelectric legs which are electrically contact-connected in series are coated so as to be covered with an electrically insulating solid material.

The invention proposes a plurality of improvements to the structure and design of the module, and these make possible both improved heat flow owing to optimized thermal coupling and also a simpler and nevertheless more flexible encapsulation of the module or of the TEG.

According to the invention, the expression “coated so as to be covered” refers to a coating which completely surrounds the entire thermoelectric module of thermoelectric legs contact-connected in series, with the exception of the electrical contact-connection which serves for supplying electrical power to and carrying it away from the thermoelectric module. The thermoelectric module is therefore coated on all sides with the electrically insulating solid material. In particular, the construction composed of thermoelectric n- and p-materials connected by electrical contacts, as shown in FIG. 2, is coated so as to be covered in the manner according to the invention. The coating may therefore lie within the two ceramic plates shown in FIG. 1, between which the individual legs for forming the thermoelectric module are applied in alternation.

Since coating takes place according to the invention, it is also possible to coat non-planar geometries of the thermoelectric legs in accordance with the invention.

The thermoelectric legs are preferably coated with the electrically insulating solid material by applying a solution or suspension or melt or vapor or a powder of the electrically insulating solid material to the thermoelectric legs, which are contact-connected in series.

The solid material can preferably be applied by spraying or immersion processes, brushing on, evaporation processes, sputtering or CVD processes.

The electrically insulating solid material is preferably selected from oxides, nitrides, silicates, ceramics, glasses, inorganic or organic polymers. By way of example, ceramics can be oxidic or nitridic. By way of example, organic polymers can be organic polymers which can withstand high temperatures, such as polyimides, for example Kapton®, or coatings based on silicone resins, as are provided for example as Fortafix®SP650 Black. For high-temperature modules, preference is given to mica, for example, and a polyimide such as Kapton® is preferred for low-temperature modules, for example.

The electrically insulating material can accordingly be applied by a spraying or immersion process, or else by a combination of these processes. Alternatively, the material can be applied by brushing. Further physical processes in which the thermoelectric module is not damaged by the process conditions, for example high temperatures, are also conceivable, for example sputtering, PVD, CVD processes or variants thereof known to a person skilled in the art.

By way of example, the electrically insulating solid material can therefore be applied by spraying processes such as plasma spraying, powder flame spraying, cold spraying, flame spraying with wire, etc., or by physical vapor deposition (PVD), such as evaporation processes or sputtering, by chemical vapor deposition (CVD), or other variants of these processes.

The electrically insulating material preferably completely surrounds the thermoelectric module, or the electrically contact-connected legs, and has a thickness sufficient for electrical insulation. The thickness of the coating is preferably 5 μm to 5 mm, particularly preferably 20 μm to 2 mm, in particular 50 μm to 1 mm.

A preferably covering metal layer can also be applied to the coating with the electrically insulating solid material. The metal layer is applied such that the electrical connections of the thermoelectric module, i.e. the lines for supplying and carrying away power, are not in electrically conductive contact with the metal layer, since otherwise the thermoelectric module would short-circuit. These lines for supplying and carrying away power are therefore also excluded from the covering metal layer.

The metal layer in turn can be applied using any desired, suitable processes. The metal layer is preferably applied by spraying, electroplating, sputtering or PVD, CVD or MOCVD processes. In general, it is possible to employ all suitable thermal, chemical, physical or electrochemical processes for applying the coating. Suitable metal spraying processes are arc wire spray and plasma spray processes, for example.

The metal layer serves to hermetically seal the entire thermoelectric module, such that material losses resulting from sublimation or evaporation and also destruction or damage resulting from oxidation or other contamination are avoided. The metal used can be any metal which is stable under the conditions of use and can be applied in the above processes. Preferred metals are molybdenum, tungsten, iron, tantalum, nickel, cobalt, chromium, copper and mixtures or alloys thereof, such as nickel-plated copper and copper-plated steel. Aluminum or zinc may also be suitable for low-temperature modules.

A combination of a plurality of metals is also possible. The first metal layer can thus be sprayed on very thinly and surrounded by electroplating with a second metal layer. This is beneficial particularly when the first metal layer still does not have a fully sealing effect, but instead still has a residual porosity or permeability.

The metal layer has a thickness sufficient for affording protection against the above-mentioned effects. The thickness of the metal layer is preferably 5 μm to 5 mm, particularly preferably 50 μm to 2 mm, in particular 100 μm to 1 mm.

The thermoelectric module is preferably initially coated so as to be covered with the electrically insulating material using a coating process and, in a second, subsequent step, is likewise surrounded so as to be covered with a metal casing.

A residual porosity of the metal coating can also be eliminated, for example by subsequent coating with a ceramic or by infiltration of a pore-closing material. The metal can thus be infiltrated with a water glass, a sol-gel precursor, a silicone or silicone resin or the like, where the infiltrating medium is then decomposed in the pores by a thermal, radiolytic or chemical treatment and closes the pores.

An individual thermoelectric module can be electrically insulated and encapsulated by the coatings, or a series of thermoelectric modules can first be electrically insulated and then encapsulated together in one step.

The construction according to the invention makes it possible to electrically insulate and then tightly encapsulate a thermoelectric module of legs which are electrically contact-connected in series of any desired geometry, which can be round, angular, planar, non-planar or asymmetric, for example. This makes it possible to achieve a continuous integral bond between all the components of the thermoelectric module. By way of example, the thermoelectric legs are initially contact-connected to one another electrically by welding, soldering, spraying (on) or applying pressure, electrical insulation is sprayed onto the electrodes or contacts and a tight encapsulation is sprayed onto the electrical insulation.

The electrical contacts of the module are led out of the module in a gas-tight manner through the metal casing. The modules according to the invention make it possible to press the transfer surfaces on the hot and cold sides of the module with high pressure onto the planar module surfaces, such that good transfer of heat and cold to the module is possible and electrical and thermal resistances are also minimized in the module itself.

The integral construction between the thermoelectric legs, the electrodes, the electrical insulation and the module encapsulation makes it possible to optimize the thermal coupling, while minimizing the electrical resistances and thermal resistances.

The production process according to the invention is uncomplicated and inexpensive and makes simple and scalable industrial production possible. The bonding of a thermoelectric module encapsulated according to the invention for use is possible in a simple manner by the connection of the encapsulation or metal coating by conventional processes, such as soldering, welding or the application of pressure.

One particular advantage is the geometric flexibility. The encapsulation by the electrical insulating material sprayed on and the metal sprayed on is not linked to a particular module design, but instead can be used for any desired module.

The metal casing is solid and may at the same time be ductile. It can thereby effectively resist and compensate for thermal and mechanical stresses, and thereby protects the thermoelectric module within it.

The construction according to the invention of the thermoelectric modules with electrical insulation and subsequent metal encapsulation as a coating makes it possible to construct a generator quickly and inexpensively, in that the “bare” thermoelectric material of thermoelectric legs which are electrically contact-connected in series is applied to a holder and this composite is electrically insulated and then encapsulated jointly in one step, producing a thermoelectric generator. It is thereby also possible to treat individual thermoelectric legs without electrical contact-connection.

The invention also relates to a thermoelectric module obtainable by the above process, and also to a thermoelectric module, wherein thermoelectric legs which are electrically contact-connected in series are coated so as to be covered with an electrically insulating solid material.

In this case, a preferably covering metal layer can be applied to the coating with the electrically insulating solid material.

The thermoelectric modules according to the invention can be used both in Peltier elements and in generator elements operated at a temperature in the range of preferably −50° C. to 2000° C., particularly preferably −30 to 1500° C., in particular −25 to 1000° C., depending on the thermal stability of the materials used.

Any desired suitable thermoelectric materials can be used in the thermoelectric modules according to the invention. Examples of these materials are skutterudites, half-Heusler materials, clathrates, oxides, silicides, borides, Bi₂Te₃ and derivatives thereof, PbTe and derivatives thereof, antimonides such as zinc antimonide and Zintl phases.

The invention is explained in more detail by the examples which follow.

### EXAMPLES

### Example 1

PbTe legs were inserted into a matrix and then electrically contact-connected with Fe electrodes. A ceramic coating of Al₂O₃ was applied homogeneously by powder flame spraying to both sides of the thermoelectric legs thereby contact-connected. A second coating of steel was then applied to the rough ceramic surfaces by plasma spraying. The metal coating thickness was about 0.5 mm, and the ceramic layer thickness was about 0.1 mm. No after-treatment was performed on the metal layer. Polishing or impregnation of the metal layer would be conceivable.

### Example 2

A commercially available Bi₂Te₃ module, in which the thermoelectric legs were only metallically electrically conductively contact-connected, but not electrically insulated, was lightly roughened using emery paper P 220. The surface was then cleaned with ethanol. Both sides of the module were then finely sprayed with an aerosol of a heat-resistant silicone coating resin (Fortafix® SP650) and dried for three hours at room temperature. The coated module was then transferred into a muffle furnace, and the coating was cured for three hours at 300° C. under a slow-moving stream of nitrogen.

We claim:

1. A process for the production of a thermoelectric module, in which process thermoelectric legs which are electrically contact-connected in series are coated so as to be covered with an electrically insulating solid material.

2. The process according to claim 1, wherein the thermoelectric legs are coated with the electrically insulating solid material by applying a solution or suspension or melt or vapor or a powder of the electrically insulating solid material to the thermoelectric legs, which are contact-connected in series.

3. The process according to claim 2, wherein the solid material is applied by spraying or immersion processes, brushing on, evaporation processes, sputtering or CVD processes.

4. The process according to claim 1, wherein the electrically insulating solid material is selected from oxides, nitrides, silicates, ceramics, glasses, inorganic or organic polymers.

5. The process according to claim 4, wherein the electrically insulating solid material is selected from mica or organic polymers which can withstand high temperatures.

6. The process according to claim 1, wherein a preferably covering metal layer is applied to the coating with the electrically insulating solid material.

7. The process according to claim 6, wherein the metal layer is applied by spraying, electroplating, sputtering or PVD, CVD or MOCVD processes.

8. The process according to claim 6, wherein a residual porosity of the metal coating is eliminated by subsequent coating with a ceramic or by infiltration of a pore-closing material.

9. The process according to claim 1, wherein the thermoelectric legs are contact-connected to one another electrically by welding, soldering, spraying (on) or applying pressure.

10. A thermoelectric module, obtainable by the process according to claim 1.

11. A thermoelectric module, wherein thermoelectric legs which are electrically contact-connected in series are coated so as to be covered with an electrically insulating solid material.

12. The thermoelectric module according to claim 11, wherein a preferably covering metal layer is applied to the coating with the electrically insulating solid material.
